(19) United States
(12) Patent Application Publication
(10) Pub. No.: US 2013/0115754 A1
(43) Pub. Date: May 9, 2013

(54) MICRO MACHINING METHOD FOR A SUBSTRATE ON AN UNDERLAY

(71) Applicants: Jing Chen, Beijing (CN); Yiming Zhang, Beijing (CN)

(72) Inventors: Jing Chen, Beijing (CN); Yiming Zhang, Beijing (CN)

(21) Appl. No.: 13/290,679

(22) Filed: Nov. 7, 2011

(51) Int. Cl. H01L 21/762

(52) U.S. Cl. 438/459; 438/675; 257/E21.567

(57) ABSTRACT

A micro machining method includes utilizing a polymer as an intermediate adhesion layer, and bonding a underlay with a substrate by pressure bonding, thinning the substrate and deep-etching it to form through holes, backfilling the through holes and deep-etching the substrate again to form a plating hole, plating metal in the plating hole to form a support between the underlay and the substrate, and dissolving the through holes, and etching the polymer through the through holes to release structures. Alternatively, after forming the substrate on the underlay, the method can include thinning the substrate and deep-etching it to form a plating hole, plating metal in the plating hole to form a support between the underlay and the substrate, deep-etching the substrate again to form through holes, and etching the polymer through the through holes to release structures.

### TECHNICAL FIELD

The present invention generally relates to Microelectromechanical System (MEMS) microfabrication technologies, and more particularly, to microfabrication of a substrate on an underlay.

### BACKGROUND OF THE INVENTION

Silicon On Insulator (SOI) technology is widely used in semiconductor and MEMS fabrication. High aspect ratio SOI MEMS technique is employed in electrostatic driven devices such as inertia sensors of simple fabrication, high efficiency, large area of capacitance electrode, small area of chips, high power load carrying capacity and high integration. However, the cost of SOI wafer is high, which impedes those applications. SOI technology uses silicon as the only structure material. The low electrical conductivity and low fracture resilience of silicon limits the performance, reliability and application of the devices. For conductive contact application, the silicon surface needs metal coating. But long term work would lead to the invalidation of the contact. Furthermore, silicon is brittle, and is unsuitable for the high impact, huge load and harsh environment, which also limits the applications of such devices.

### SUMMARY OF THE INVENTION

The present invention overcomes many disadvantages of the existing technologies, providing a micro machining method for fabricating MEMS devices on a substrate on an underlay.

The present invention realizes low cost, high precision, high aspect ratio three dimensional fabrication using different kinds of materials. The disclosed methods are compatible with CMOS process and can used to manufacture many MEMS devices.

A micro machining method for a substrate on an underlay can include:

1) Utilizing a polymer as an intermediate adhesion layer, and bonding the underlay with the substrate to form the substrate on the underlay by pressure bonding process;

2) Thinning the substrate and deep-etching it to form through holes;

3) Backfilling the through holes and deep-etching the substrate again to form a plating hole;

4) Plating metal in the plating hole to form a support between the underlay and the substrate;

5) Dissolving the through holes and etching the polymer through the through holes to release structures.

A micro machining method for a substrate on an underlay can include:

1) Utilizing a polymer as an intermediate adhesion layer, and bonding the underlay with the substrate to form the substrate on the underlay by pressure bonding process;

2) Thinning the substrate and deep-etching it to form a plating hole;

3) Plating metal in the plating hole to form a support between the underlay and the substrate;

4) Deep-etching the substrate again to form through holes;

5) Etching the polymer through the through holes to release structures.

In the step 1) of the above two methods, the metal routing is on the underlay and this metal layer is under the plating holes.

In the above described methods, the substrate can be made of glass, silicon, titanium, aluminum, or molybdenum.

In the above described methods, the underlay can be made of silicon, germanium, III-V compound, titanium, aluminum, or molybdenum.

In the above described methods, the polymer can include SU8 photo resist, BCB, Polyimide, PMMA, or AZ photo resist.

In the above described methods, the metal is aurum, copper, nickel, or stannum. The present invention combines pressure bonding, chemical mechanical polishing, deep etching and plating process, realizing various kinds of materials low cost, high precision, high aspect ratio three dimension fabrication. Compatible with CMOS process, the methods could be used to manufacture many MEMS devices.

The use of metal as the structure material can make low contact resistance, high and increase the reliability of the system. The devices can work in the harsh environment.

Moreover, metal routing on the substrate, connecting with the structure layer by plating process, forms metal system on the substrate, realizing the cross interconnection and multi-layer interconnection.

### BRIEF DESCRIPTION OF THE DRAWINGS

FIG. 1(a)-1(r) are a cross-sectional side views illustrating steps for forming a substrate on an underlay in accordance to an embodiment of the present invention.

FIGS. 2(a)-2(p) are cross-sectional side views illustrating steps for forming a substrate on an underlay in accordance to another embodiment of the present invention.

### DETAILED DESCRIPTION OF THE INVENTION

In one embodiment, the plating holes are formed after etching through holes.

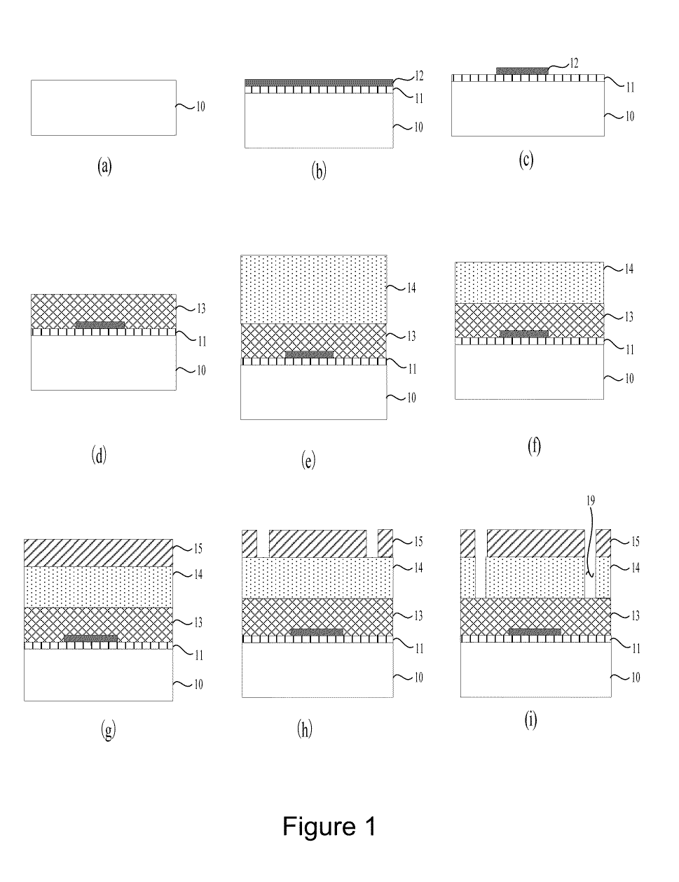

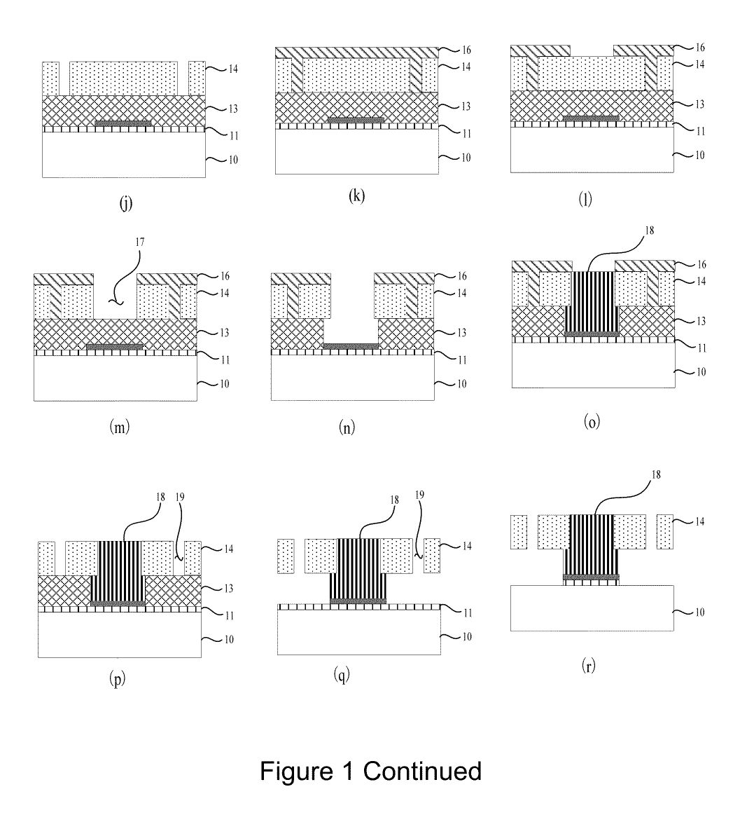

1. FIG. 1(a) shows the underlay 10, which can be made of glass, silicon, titanium, aluminum, or molybdenum.

2. Metal or metal compound layer 11 is formed on the underlay 10, then the layer 12 is patterned. The layer 11 can formed by sputtering, for example, to form a 30 nm thick chromium layer.

3. Then another metal or metal compound layer 12 can be formed on the layer 11 by sputtering 500 nm thick Au layer for instance, as shown in FIG. 1(b), and patterned, as shown in FIG. 1(c).

4. A polymer 13, e.g. 5 μm thick benzocyclobutene (BCB) is formed on the underlay 10 as shown in FIG. 1(d). A substrate 14 is then adhesive bonded with the underlay 10 as shown in FIG. 1(e). The substrate material can include silicon, germanium, III-V compound, titanium, aluminum, or molybdenum.

5. The substrate 14 is thinned and etched to form through holes 19. FIG. 1(f) shows that the substrate 14 is thinned by chemical mechanical polishing to appropriate thickness, like 40-100 μm.

FIG. 1(h) shows that the deep etching mask 15 is formed and patterned on the surface of the substrate 14, 50 um thick SU8 or metal layer for example.

FIG. 1(i) shows that the substrate is etched through by deep etching.

6. The mask 15 on the surface of the substrate 14 is removed and the through holes 19 are filled, for example by parylene, as shown in FIG. 1(k), resulting a backfilling layer 16 on the substrate 14.

7. The backfilling layer 16 is patterned (FIG. 1(l)).

8. The substrate 14 is deep-etched to form plating holes 17, as shown in FIG. 1(m). Some polymer is removed as shown in FIG. 1(n).

9. FIG. 1(o) shows that the metal layer 18 is plated in the plating hole 17 to form a support. The plating metal can include gold, copper, nickel, or stannum.

10. The backfilling layer 16 is then removed to expose the through holes 19 as shown in FIG. 1(p).

11. The polymer 13 is etched via the through holes 19 to release structures, as shown in FIG. 1(q). For example, polymer BCB is etched by the mixed gas of fluorine-based gas and oxygen.

12. The metal layer 11 is partly removed as shown in FIG. 1(r).

In another embodiment, the plating holes are formed before etching through holes.

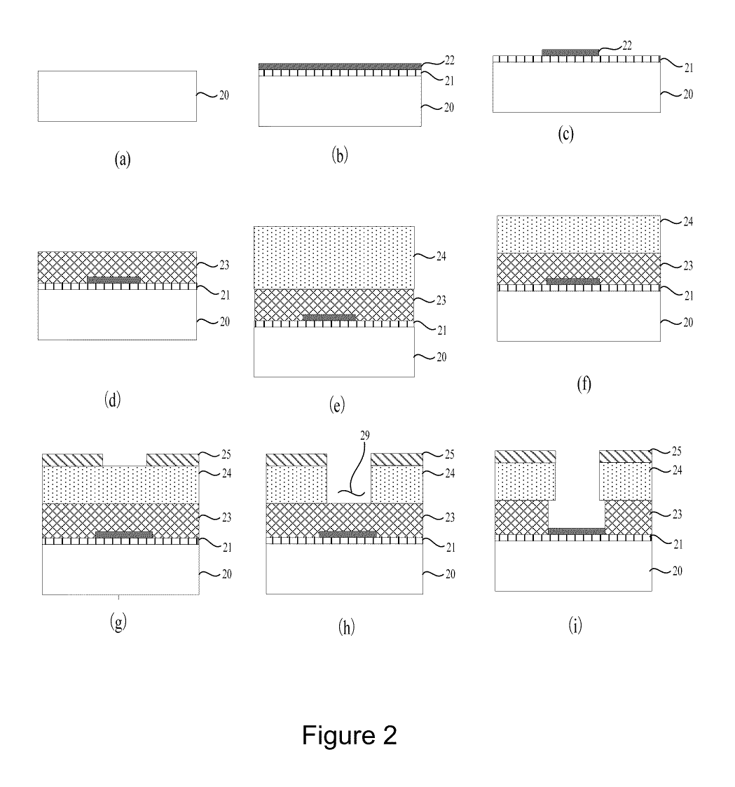

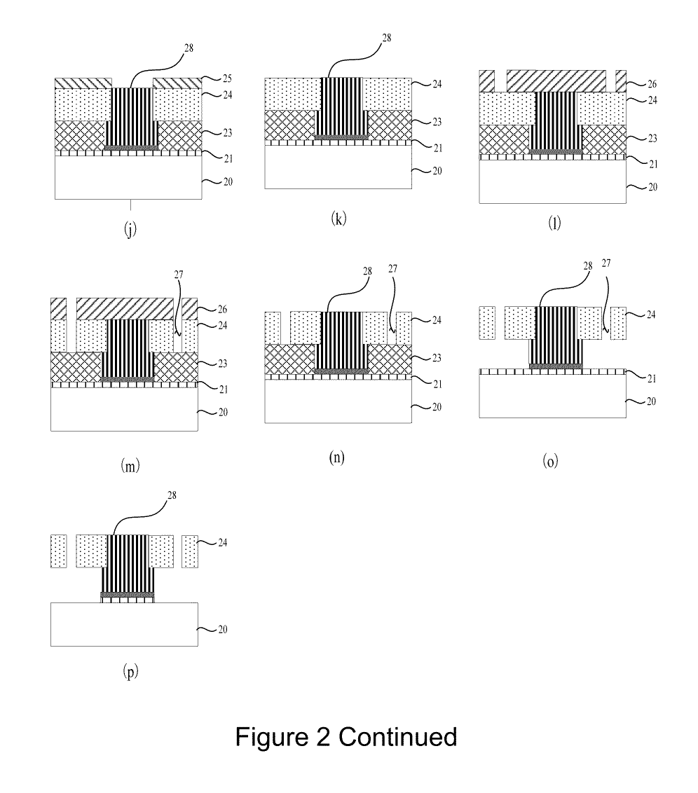

1. FIG. 2(a) shows the underlay 20, which can be made of glass, silicon, titanium, aluminum, or molybdenum.

2. Metal or metal compound layer 21 and layer 22 is formed on the underlay, then the layer 2 is patterned.

3. The layer 21 is formed by sputtering, to form, for example, a 30 nm thick chromium layer as shown in FIG. 2(b). Then layer 22 is formed and patterned on the layer 21, referring to FIG. 2(c). The layer 22 can be a 500 nm thick Au layer.

4. The substrate 24 and the underlay 20 are bonded utilizing a polymer as an intermediate adhesion layer. The substrate material could be silicon, germanium, III-V compound, titanium, aluminum, or molybdenum. A polymer 23, e.g. 5 um thick benzocyclobutene (BCB) is formed on the underlay as shown in FIG. 2(d), and then adhesive bonded with the substrate as shown in FIG. 2(e).

5. The substrate 24 is thinned and etched to form the through holes 29.

FIG. 2(f) shows that the substrate 24 is thinned by chemical mechanical polishing to appropriate thickness, like 40-100 um.

FIG. 2(g) shows that the deep etching mask 25 is formed on the surface of the substrate, 50 um thick SU8 or metal layer for example, and patterned.

FIG. 2(h) shows that the substrate 24 is etched through by deep etching to form the plating holes 29.

The polymer 23 under the plating hole 29 is removed, as shown in FIG. 2(i).

6. A metal layer 28 is plated in the plating holes 29 as shown in FIG. 2(j). The plating metal can include gold, copper, nickel, or stannum.

7. The mask 25 on the surface of the substrate 24 is removed as shown in FIG. 2(k).

8. FIG. 2(l) shows that a deep etching mask 26 is formed and patterned on the substrate 24 and the metal layer.

9. FIG. 2(m) shows that the substrate 24 is etched through by deep etching to form through holes 27.

10. The mask 26 on the substrate 24 is removed as shown in FIG. 2(n). The polymer 23 is removed by etchant introduced through the through holes 27 to release structures, as shown in FIG. 2(o). For example, polymer BCB is etched by the mixed gas of fluorine-based gas and oxygen.

11. The metal layer 21 on the underlay is partly removed as shown in FIG. 2(p).

The above described applications and structures are only illustrative. Those skilled in the art will recognize many other applications or structures that can benefit considerably from the use of a micro machining method for a substrate on an underlay.

It should be understood that the above described detailed implementation and figures are aimed at helping readers to understand the present invention and implement accordingly. However, as practitioners in this field can appreciate, the present invention can be implemented in different variations and with approaches without deviating from the spirit of the invention. It should be understood that the scope of the prevent invention is not limited to the specific implementations and examples described above.

What is claimed is:

1. A micro machining method for a substrate on an underlay, comprising:
bonding an underlay to a substrate using a polymer as an intermediate adhesion layer;
thinning the substrate;
forming through holes in the substrate by deep-etching;
backfilling the through holes;
deep-etching the substrate again to form a plating hole;
plating metal in the plating hole to form a support between the underlay and the substrate;
dissolving the through holes; and
removing the polymer through the through holes to release structures.

2. A method according to claim 1, wherein the metal routing is on the underlay and this metal layer is under the plating holes.

3. A method according to claim 1, wherein the underlay comprises glass, silicon, titanium, aluminum or molybdenum.

4. A method according to claim 1, wherein the substrate comprises silicon, germanium, III-V compound, titanium, aluminum or molybdenum.

5. A method according to claim 1, wherein the polymer comprises photoresist, SU-8, BCB, Polyimide, PMMA, or AZ series photoresist.

6. A method according to claim 1, wherein the plating metal comprises gold, copper, nickel, or stannum.

7. A micro machining method for a substrate on an underlay, comprising:
forming an intermediate adhesion layer comprising a polymer on a underlay;
bonding a substrate to the underlay by pressure bonding;
thinning the substrate and deep-etching it to form a plating hole;
plating metal in the plating hole to form a support between the underlay and the substrate;
forming through holes in the substrate by deep-etching; and
removing the polymer through the through holes to release structures.

8. A method according to claim 7, wherein the metal routing is on the underlay and this metal layer is under the plating holes.

9. A method according to claim 7, wherein the underlay is glass, silicon, titanium, aluminum or molybdenum.

10. A method according to claim 7, wherein the substrate is silicon, germanium, III-V compound, titanium, aluminum or molybdenum.

11. A method according to claim 7, wherein the polymer is photoresist, SU-8, BCB, Polyimide, PMMA, or AZ series photoresist.

12. A method according to claim 7, wherein the plating metal is gold, copper, nickel, or stannum.
